(19) United States
(12) Patent Application Publication
(10) Pub. No.: US 2025/0237942 A1
(43) Pub. Date: Jul. 24, 2025

(54) PHOTOMASK DESIGN METHOD, SEMICONDUCTOR MANUFACTURING PROCESS, AND SEMICONDUCTOR STRUCTURE

(71) Applicant: United Microelectronics Corp., Hsinchu (TW)

(72) Inventor: Chia-Chen Sun, Kaohsiung City (TW)

(73) Assignee: United Microelectronics Corp., Hsinchu (TW)

(21) Appl. No.: 18/433,454

(22) Filed: Feb. 6, 2024

(30) Foreign Application Priority Data
Jan. 19, 2024 (TW) 113102162

(51) Int. Cl. G03F 1/70; G03F 1/38; H01L 21/027

(52) U.S. Cl. CPC G03F 1/70; G03F 1/38; H01L 21/0274

(57) ABSTRACT

A photomask design method including the following steps is provided. Photomask layout designs are provided, wherein the photomask layout designs have overall aperture ratios, and each of the photomask layout designs includes a first device region and a first dummy region. The aperture ratio of the first dummy region of at least one of the photomask layout designs is adjusted to reduce the overall aperture ratio difference between the photomask layout designs.

### CROSS-REFERENCE TO RELATED APPLICATION

This application claims the priority benefit of Taiwan application serial no. 113102162, filed on Jan. 19, 2024. The entirety of the above-mentioned patent application is hereby incorporated by reference herein and made a part of this specification.

### BACKGROUND

### Technical Field

The invention relates to a photomask design method, a semiconductor manufacturing process, and a semiconductor structure, and particularly relates to a photomask design method, a semiconductor manufacturing process, and a semiconductor structure which can prevent the deviation in the size of the component.

### Description of Related Art

In the semiconductor manufacturing process, the photomasks have the overall aperture ratios. When the overall aperture ratio difference between the photomasks is too large, it will lead to the deviations in the pattern sizes of the patterned photoresist layers formed by the photomasks. Therefore, when the subsequent processes are performed by using the above patterned photoresist layers, there will be a deviation in the size of the component formed by the subsequent process.

### SUMMARY

The invention provides a photomask design method, a semiconductor manufacturing process, and a semiconductor structure, which can prevent the deviation in the size of the component.

The invention provides a photomask design method, which includes the following steps. The photomask layout designs are provided, wherein the photomask layout designs have overall aperture ratios, and each of the photomask layout designs includes a first device region and a first dummy region. The aperture ratio of the first dummy region of at least one of the photomask layout designs is adjusted to reduce the overall aperture ratio difference between the photomask layout designs.

According to an embodiment of the invention, in the photomask design method, after adjusting the aperture ratio of the first dummy region of at least one of the photomask layout designs, the overall aperture ratio difference between any two of the photomask layout designs may range from 0% to 20%.

According to an embodiment of the invention, in the photomask design method, after adjusting the aperture ratio of the first dummy region of at least one of the photomask layout designs, the overall aperture ratio difference between any two of the photomask layout designs may range from 0% to 15%.

According to an embodiment of the invention, in the photomask design method, after adjusting the aperture ratio of the first dummy region of at least one of the photomask layout designs, the overall aperture ratio difference between any two of the photomask layout designs may range from 0% to 10%.

According to an embodiment of the invention, in the photomask design method, after adjusting the aperture ratio of the first dummy region of at least one of the photomask layout designs, the overall aperture ratio difference between any two of the photomask layout designs may range from 0% to 5%.

According to an embodiment of the invention, in the photomask design method, the method of adjusting the aperture ratio of the first dummy region of at least one of the photomask layout designs may include increasing the aperture ratio of the first dummy region of at least one of the photomask layout designs.

According to an embodiment of the invention, in the photomask design method, the method of adjusting the aperture ratio of the first dummy region of at least one of the photomask layout designs may include reducing the aperture ratio of the first dummy region of at least one of the photomask layout designs.

The invention provides a semiconductor manufacturing process, which includes the following steps. Photomasks formed by the above photomask design method are provided. A substrate is provided, wherein the substrate includes a second device region and a second dummy region, the second device region corresponds to the first device region, the second dummy region corresponds to the first dummy region, the substrate has a fin portion and a dummy fin portion, the fin portion is located in the second device region, and the dummy fin portion is located in the second dummy region. Ion implantation processes are performed on the substrate by using patterned photoresist layers as masks, wherein the patterned photoresist layers are formed by performing lithography processes by using the photomasks. After performing the ion implantation processes, the top-view pattern of the top surface of the dummy fin portion has various widths.

According to an embodiment of the invention, in the semiconductor manufacturing process, at least two of the ion implantation processes may dope different area ranges of the dummy fin portion. The different area ranges may have an overlapping area.

According to an embodiment of the invention, in the semiconductor manufacturing process, at least two of the ion implantation processes may dope different area ranges of the dummy fin portion. The different area ranges may be separated from each other.

According to an embodiment of the invention, in the semiconductor manufacturing process, the contour of the top-view pattern of the top surface of the dummy fin portion may include an irregular shape.

According to an embodiment of the invention, in the semiconductor manufacturing process, the contour of the top-view pattern of the top surface of the dummy fin portion may include a curved line.

According to an embodiment of the invention, in the semiconductor manufacturing process, the contour of the top-view pattern of the top surface of the dummy fin portion may include a wavy shape.

According to an embodiment of the invention, in the semiconductor manufacturing process, the contour of the top-view pattern of the top surface of the dummy fin portion may include a tip.

The invention provides a semiconductor structure, which includes a substrate. The substrate includes a device region and a dummy region. The substrate has a fin portion and a dummy fin portion. The fin portion is located in the device region. The dummy fin portion is located in the dummy region. The top-view pattern of the top surface of the dummy fin portion has various widths.

According to an embodiment of the invention, in the semiconductor structure, the contour of the top-view pattern of the top surface of the dummy fin portion may include an irregular shape.

According to an embodiment of the invention, in the semiconductor structure, the contour of the top-view pattern of the top surface of the dummy fin portion may include a curved line.

According to an embodiment of the invention, in the semiconductor structure, the contour of the top-view pattern of the top surface of the dummy fin portion may include a wavy shape.

According to an embodiment of the invention, in the semiconductor structure, the contour of the top-view pattern of the top surface of the dummy fin portion may include a tip.

According to an embodiment of the invention, in the semiconductor structure, the top-view pattern of the top surface of the fin portion may have a uniform width.

Based on the above description, in the photomask design method and the semiconductor manufacturing process according to the invention, the aperture ratio of the first dummy region of at least one of the photomask layout designs is adjusted to reduce the overall aperture ratio difference between the photomask layout designs. Therefore, the deviation in the size of the component (e.g., doped region) formed by the subsequent process (e.g., ion implantation process) can be prevented. In addition, after the above semiconductor manufacturing process is performed, the top-view pattern of the top surface of the dummy fin portion in the semiconductor structure has various widths.

In order to make the aforementioned and other objects, features and advantages of the invention comprehensible, several exemplary embodiments accompanied with drawings are described in detail below.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention.

FIG. 1 is a flow chart of a photomask design method according to some embodiments of the invention.

FIG. 2 is a top view of photomask layout designs according to some embodiments of the invention.

FIG. 3 is a top view of the photomask layout designs after adjusting the aperture ratio of the dummy region of the photomask layout design.

FIG. 4 is a flow chart of a semiconductor manufacturing process according to some embodiments of the invention.

FIG. 5 is a partial top view of photomasks according to some embodiments of the invention.

FIG. 6 is a partial top view of a substrate according to some embodiments of the invention.

FIG. 7 is a partial top view of a patterned photoresist layer and a substrate according to some embodiments of the invention.

FIG. 8 is a partial top view of a patterned photoresist layer and a substrate according to other embodiments of the invention.

FIG. 9 is a partial perspective view of a semiconductor structure according to some embodiments of the invention.

FIG. 10 is a partial perspective view of a semiconductor structure according to other embodiments of the invention.

FIG. 11 is a partial perspective view of a semiconductor structure according to other embodiments of the invention.

### DESCRIPTION OF THE EMBODIMENTS

The embodiments are described in detail below with reference to the accompanying drawings, but the embodiments are not intended to limit the scope of the invention. For the sake of easy understanding, the same components in the following description will be denoted by the same reference symbols. In addition, the drawings are for illustrative purposes only and are not drawn to the original dimensions. Furthermore, the features in the top view and the features in the perspective view are not drawn to the same scale. In fact, the dimensions of the various features may be arbitrarily increased or reduced for clarity of discussion.

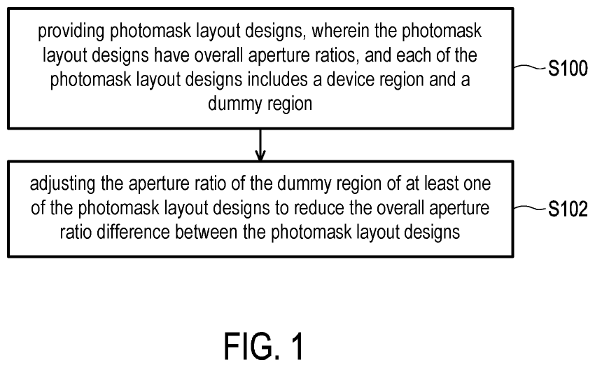

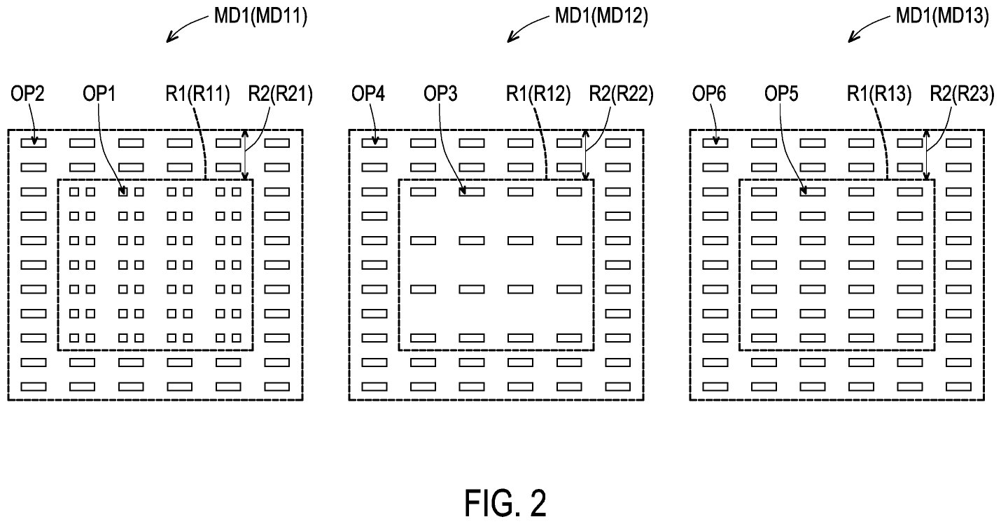

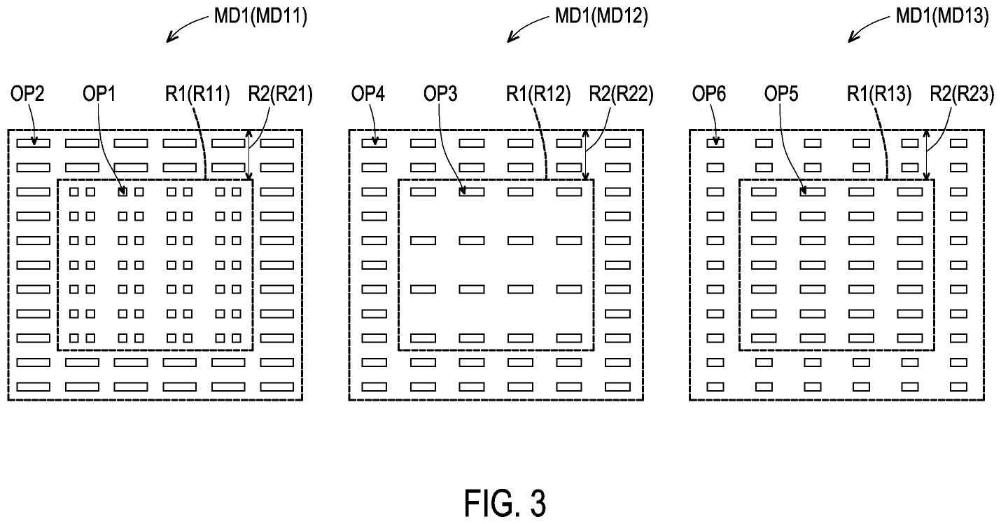

FIG. 1 is a flow chart of a photomask design method according to some embodiments of the invention. FIG. 2 is a top view of photomask layout designs according to some embodiments of the invention. FIG. 3 is a top view of the photomask layout designs after adjusting the aperture ratio of the dummy region of the photomask layout design.

Referring to FIG. 1A, in the step S100, photomask layout designs are provided, wherein the photomask layout designs have overall aperture ratios, and each of the photomask layout designs includes a device region and a dummy region.

In some embodiments, as shown in FIG. 2, photomask layout designs MD1 have overall aperture ratios. Each of the photomask layout designs MD1 includes a device region R1 and a dummy region R2. In some embodiments, the dummy region R2 may surround the device region R1. In some embodiments, the photomask layout designs MD1 may include a photomask layout design MD11, a photomask layout design MD12, and a photomask layout design MD13. In some embodiments, the overall aperture ratio of the photomask layout design MD12 may be greater than the overall aperture ratio of the photomask layout design MD11, and the overall aperture ratio of the photomask layout design MD13 may be greater than the overall aperture ratio of the photomask layout design MD12. In addition, the number of the photomask layout designs MD1 is not limited to the number in the figure. As long as the number of the photomask layout designs MD1 is plural, it falls within the scope of the invention.

The photomask layout design MD11 may include openings OP1 and openings OP2. The openings OP1 may be located in the device region R11. The openings OP2 may be located in the dummy region R21. The photomask layout design MD12 may include openings OP3 and openings OP4. The openings OP3 may be located in the device region R12. The openings OP4 may be located in the dummy region R22. The photomask layout design MD13 may include openings OP5 and openings OP6. The openings OP5 may be located in the device region R13. The openings OP6 may be located in the dummy region R23. In some embodiments, the layout design of the openings OP1 in the device region R11, the layout design of the openings OP3 in the device region R12, and the layout design of the openings OP5 in the device region R13 may be different from each other. In some embodiments, the layout design of the openings OP2 in the dummy region R21, the layout design of the openings OP4 in the dummy region R22, and the layout design of the openings OP6 in the dummy region R23 may be the same as each other or different from each other.

Referring to FIG. 1, in the step S102, the aperture ratio of the dummy region of at least one of the photomask layout designs is adjusted to reduce the overall aperture ratio difference between the photomask layout designs. In some embodiments, after adjusting the aperture ratio of the dummy region of at least one of the photomask layout designs, the overall aperture ratio difference between any two of the photomask layout designs may range from 0% to 20%. In some embodiments, after adjusting the aperture ratio of the dummy region of at least one of the photomask layout designs, the overall aperture ratio difference between any two of the photomask layout designs may range from 0% to 15%. In some embodiments, after adjusting the aperture ratio of the dummy region of at least one of the photomask layout designs, the overall aperture ratio difference between any two of the photomask layout designs may range from 0% to 10%. In some embodiments, after adjusting the aperture ratio of the dummy region of at least one of the photomask layout designs, the overall aperture ratio difference between any two of the photomask layout designs may range from 0% to 5%.

In some embodiments, the method of adjusting the aperture ratio of the dummy region of at least one of the photomask layout designs may include increasing the aperture ratio of the dummy region of at least one of the photomask layout designs. For example, as shown in FIG. 3, the aperture ratio of the dummy region R21 of the photomask layout design MD11 may be increased. In some embodiments, the size (e.g., length and/or width) of the opening OP2 in the dummy region R21 may be increased and/or the number of the openings OP2 in the dummy region R21 may be increased to increase the aperture ratio of the dummy region R21 of the photomask layout design MD11. In the present embodiment, the aperture ratio of the dummy region R21 of the photomask layout design MD11 may be increased by increasing the length of the opening OP2 in the dummy region R21, but the invention is not limited thereto.

In some embodiments, the method of adjusting the aperture ratio of the dummy region of at least one of the photomask layout designs may include reducing the aperture ratio of the dummy region of at least one of the photomask layout design. For example, as shown in FIG. 3, the aperture ratio of the dummy region R23 of the photomask layout design MD13 may be reduced. In some embodiments, the size (e.g., length and/or width) of the opening OP6 in the dummy region R23 may be reduced and/or the number of the openings OP6 in the dummy region R23 may be reduced to reduce the aperture ratio of the dummy region R23 of the photomask layout design MD13. In the present embodiment, the aperture ratio of the dummy region R23 of the photomask layout design MD13 may be reduced by reducing the length of the opening OP6 in the dummy region R23, but the invention is not limited thereto.

In some embodiments, the aperture ratio of the dummy region R2 of at least one of the photomask layout designs MD1 may be adjusted by the above method, thereby reducing the overall aperture ratio difference between the photomask layout designs MD1.

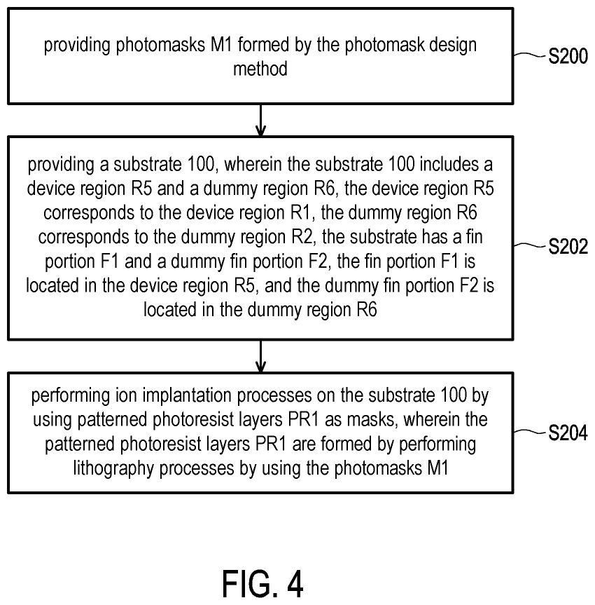

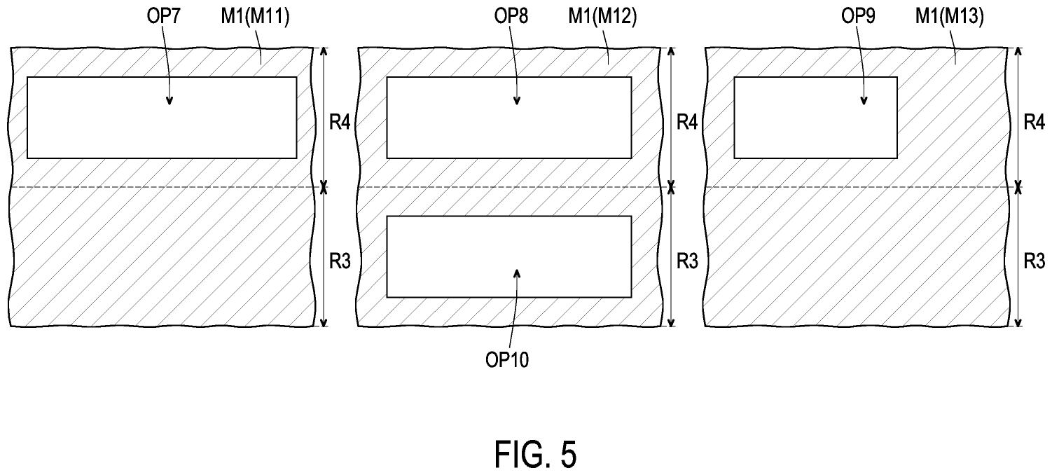

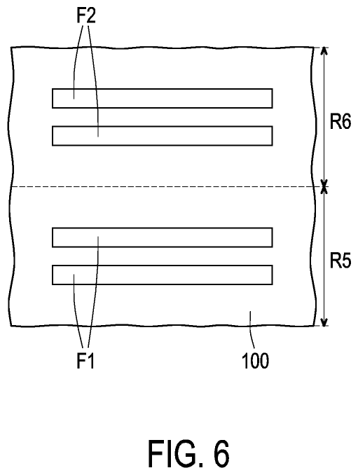

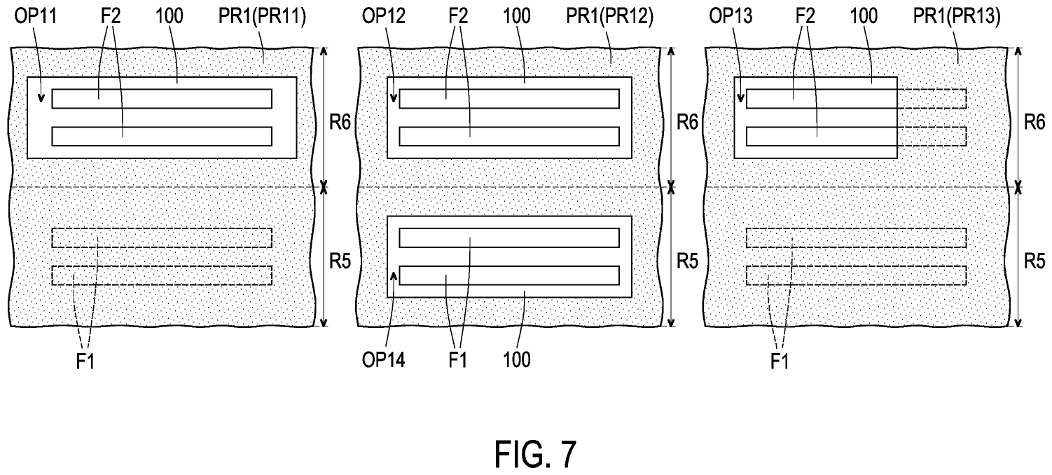

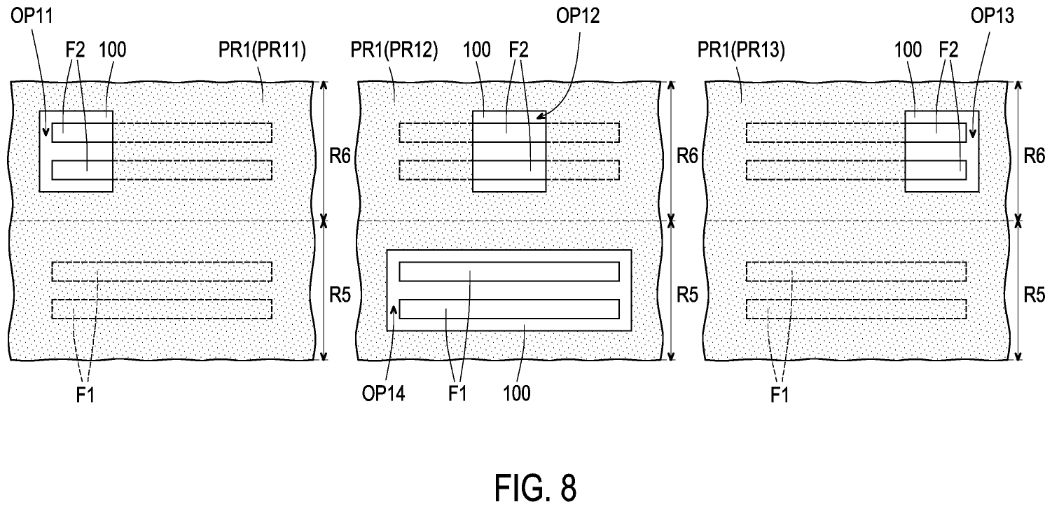

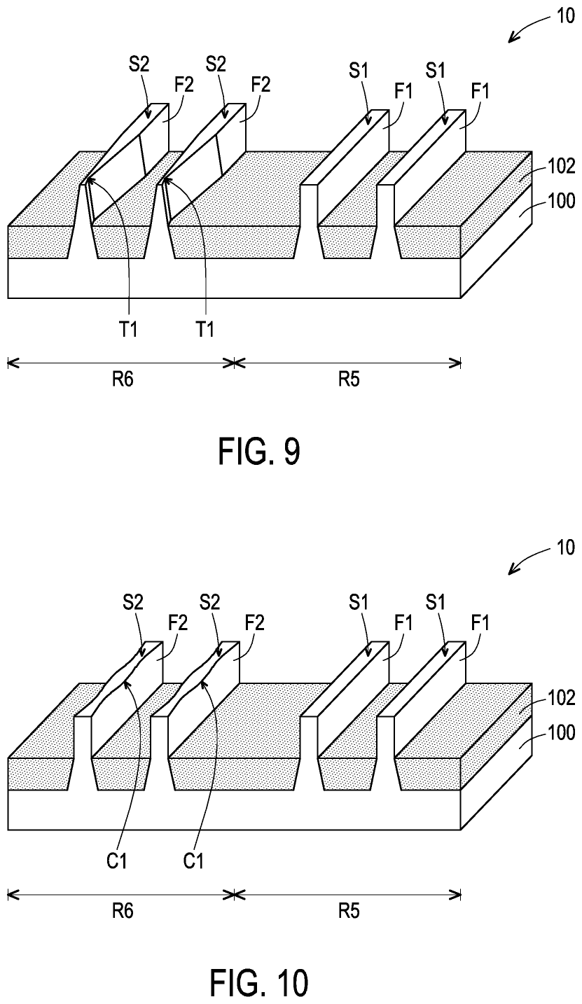

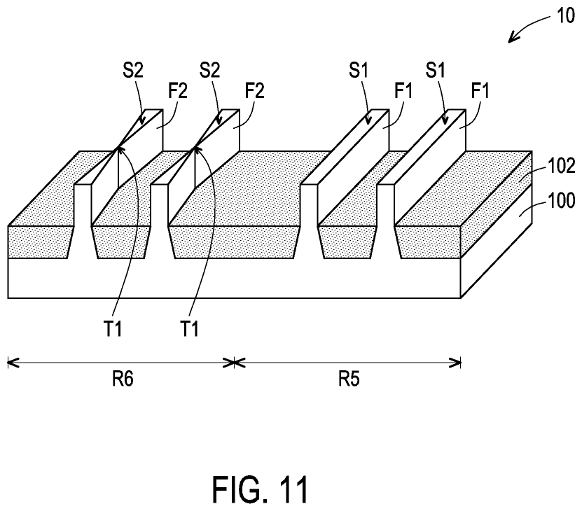

FIG. 4 is a flow chart of a semiconductor manufacturing process according to some embodiments of the invention. FIG. 5 is a partial top view of photomasks according to some embodiments of the invention. FIG. 6 is a partial top view of a substrate according to some embodiments of the invention. FIG. 7 is a partial top view of a patterned photoresist layer and a substrate according to some embodiments of the invention. FIG. 8 is a partial top view of a patterned photoresist layer and a substrate according to other embodiments of the invention. FIG. 9 is a partial perspective view of a semiconductor structure according to some embodiments of the invention. FIG. 10 is a partial perspective view of a semiconductor structure according to other embodiments of the invention. FIG. 11 is a partial perspective view of a semiconductor structure according to other embodiments of the invention.

Referring to FIG. 4 and FIG. 5, in the step S200, photomasks M1 formed by the photomask design method of FIG. 1 are provided. Each of the photomasks M1 includes a device region R3 and a dummy region R4. The device region R3 of the photomask M1 may correspond to the device region R1 of the photomask layout design MD1. The dummy region R4 of the photomask M1 may correspond to the dummy region R2 of the photomask layout design MD1. In some embodiments, the photomasks M1 may include a photomask M11, a photomask M12, and photomask M13. In some embodiments, the opening OP7 in the dummy region R4 of the photomask M11 may be greater than the opening OP8 in the dummy region R4 of the photomask M12, and the opening OP8 in the dummy region R4 of the photomask M12 may be greater than the opening OP9 in the dummy region R4 of the photomask M13, but the invention is not limited thereto. In some embodiments, there may be an opening OP10 in the device region R3 of the photomask M12. In addition, the number of the photomasks M1 is not limited to the number in the figure. As long as the number of the photomasks M1 is plural, it falls within the scope of the invention.

Referring to FIG. 4 and FIG. 6, in the step S202, a substrate 100 is provided, wherein the substrate 100 includes a device region R5 and a dummy region R6, the device region R5 corresponds to the device region R1, the dummy region R6 corresponds to the dummy region R2, the substrate has a fin portion F1 and a dummy fin portion F2, the fin portion F1 is located in the device region R5, and the dummy fin portion F2 is located in the dummy region R6. In some embodiments, the device region R5 of the substrate 100 may correspond to the device region R3 of the photomask M1, and the dummy region R6 of the substrate 100 may correspond to the dummy region R4 of the photomask M1. In some embodiments, the dummy region R6 may be a region of the substrate 100 that is not used to form any semiconductor device (e.g., active device or passive device).

Referring to FIG. 4 and FIG. 7, in the step S204, ion implantation processes are performed on the substrate 100 by using patterned photoresist layers PRI as masks, wherein the patterned photoresist layers PRI are formed by performing lithography processes by using the photomasks M1. Therefore, the desired doping region (not shown) may be formed in the substrate 100. In some embodiments, the patterned photoresist layers PRI may include a patterned photoresist layer PR11, a patterned photoresist layer PR12, and a patterned photoresist layer PR13. In some embodiments, the patterned photoresist layer PR11 may be formed by performing a lithography process by using the photomask M11, the patterned photoresist layer PR12 may be formed by performing a lithography process by using the photomask M12, and the patterned photoresist layer PR13 may be formed by performing a lithography process by using the photomask M13. In some embodiments, the opening OP11 of the patterned photoresist layer PR11 may be greater than the opening OP12 of the patterned photoresist layer PR12, and the opening OP12 of the patterned photoresist layer PR12 may be greater than the opening OP13 of the patterned photoresist layer PR13, but the invention is not limited thereto. In addition, the number of the patterned photoresist layers PRI is not limited to the number in the figure. As long as the number of the patterned photoresist layers PRI is plural, it falls within the scope of the invention.

In some embodiments, the ion implantation processes may be performed on the substrate 100 by using the patterned photoresist layer PR11, the patterned photoresist layer PR12, and the patterned photoresist layer PR13 as masks. For example, the patterned photoresist layer PR11 may be formed, and then the ion implantation process may be performed on the substrate 100 by using the patterned photoresist layer PR11 as a mask. Next, the patterned photoresist layer PR11 may be removed. Next, the patterned photoresist layer PR12 may be formed, and then the ion implantation process may be performed on the substrate 100 by using the patterned photoresist layer PR12 as a mask. Next, the patterned photoresist layer PR12 may be removed. Next, the patterned photoresist layer PR13 may be formed, and then the ion implantation process may be performed on the substrate 100 by using the patterned photoresist layer PR13 as a mask. Next, the patterned photoresist layer PR13 may be removed.

In the present embodiment, the opening OP11 of the patterned photoresist layer PR11 may expose the dummy fin portion F2 in the dummy region R6, the opening OP12 of the patterned photoresist layer PR12 may expose the dummy fin portion F2 in the dummy region R6, and the opening OP13 of the patterned photoresist layer PR13 may partially expose the dummy fin portion F2 in the dummy region R6, but the invention is not limited thereto. The area range of the dummy fin portion F2 exposed by the opening of the patterned photoresist layer PRI (e.g., the opening OP11 of the patterned photoresist layer PR11, the opening OP12 of the patterned photoresist layer PR12, or the opening OP13 of the patterned photoresist layer PR13) may vary according to the adjustment method of the aperture ratio of the dummy region R2 of the mask layout design MD1. In addition, the opening of the patterned photoresist layer PRI (e.g., the opening OP14 of the patterned photoresist layer PR12) may expose the corresponding fin portion F1 according to the product requirement.

In addition, at least two of the ion implantation processes may dope different area ranges of the dummy fin portion F2. In the present embodiment, as shown in FIG. 7, the different area ranges (e.g., the area range of the dummy fin portion F2 exposed by the opening OP12 and the area range of the dummy fin portion F2 exposed by the opening OP13) may have an overlapping area, but the invention is not limited thereto. In other embodiments, as shown in FIG. 8, the different area ranges (e.g., the area range of the dummy fin portion F2 exposed by the opening OP11, the area range of the dummy fin portion F2 exposed by the opening OP12, and the area range of the dummy fin portion F2 exposed by the opening OP13) may be separated from each other.

In addition, as shown in FIG. 9, after performing the ion implantation processes, since the ion implantation processes will cause damage to the dummy fin portion F2, the top-view pattern of the top surface S2 of the dummy fin portion F2 has various widths. Hereinafter, the semiconductor structure 10 of the above embodiment is described with reference to FIG. 9. In addition, although the method for forming the semiconductor structure 10 is described by taking the above method as an example, the invention is not limited thereto.

Referring to FIG. 9, the semiconductor structure 10 includes a substrate 100. In some embodiments, the substrate 100 may be a semiconductor substrate such as a silicon substrate. The substrate 100 includes a device region R5 and a dummy region R6. The substrate 100 has a fin portion F1 and a dummy fin portion F2. The fin portion F1 is located in the device region R5. The dummy fin portion F2 is located in the dummy region R6. The top-view pattern of the top surface S2 of the dummy fin portion F2 has various widths. In some embodiments, the top-view pattern of the top surface S1 of the fin portion F1 may have a uniform width. In some embodiments, the semiconductor structure 10 may further include an isolation structure 102. The isolation structure 102 is located on the substrate 100. The isolation structure 102 may be located on two sides of the fin portion F1 and two sides of the dummy fin portion F2. In some embodiments, the isolation structure 102 is, for example, a shallow trench isolation (STI) structure. In some embodiments, the material of the isolation structure 102 is, for example, silicon oxide.

In the present embodiment, the top-view pattern of the top surface S2 of the dummy fin portion F2 is, for example, the pattern in FIG. 9, but the invention is not limited thereto. In other embodiments, the top-view pattern of the top surface S2 of the dummy fin portion F2 may be the pattern as shown in FIG. 10 or FIG. 11. In some embodiments, as shown in FIG. 9 to FIG. 11, the contour of the top-view pattern of the top surface S2 of the dummy fin portion F2 may include an irregular shape. In some embodiments, as shown in FIG. 10, the contour of the top-view pattern of the top surface S2 of the dummy fin portion F2 may include a curved line C1. In some embodiments, as shown in FIG. 10, the contour of the top-view pattern of the top surface S2 of the dummy fin portion F2 may include a wavy shape. In some embodiments, as shown in FIG. 9 and FIG. 11, the contour of the top-view pattern of the top surface S2 of the dummy fin portion F2 may include a tip T1.

Based on the above embodiments, in the above photomask design method and the above semiconductor manufacturing process, the aperture ratio of the dummy region R2 of at least one of the photomask layout designs MD1 is adjusted to reduce the overall aperture ratio difference between the photomask layout designs MD1. Therefore, the deviation in the size of the component (e.g., doped region) formed by the subsequent process (e.g., ion implantation process) can be prevented. In addition, after the semiconductor manufacturing process is performed, the top-view pattern of the top surface S2 of the dummy fin portion F2 in the semiconductor structure 10 has various widths.

In summary, in the photomask design method and the semiconductor manufacturing process of the aforementioned embodiments, the aperture ratio of the dummy region of at least one of the photomask layout designs is adjusted to reduce the overall aperture ratio difference between the photomask layout designs. Therefore, the deviation in the size of the component (e.g., doped region) formed by the subsequent process (e.g., ion implantation process) can be prevented. In addition, after the semiconductor manufacturing process is performed, the top-view pattern of the top surface of the dummy fin portion in the semiconductor structure has various widths.

Although the invention has been described with reference to the above embodiments, it will be apparent to one of ordinary skill in the art that modifications to the described embodiments may be made without departing from the spirit of the invention. Accordingly, the scope of the invention is defined by the attached claims not by the above detailed descriptions.

What is claimed is:

1. A photomask design method, comprising:
providing photomask layout designs, wherein the photomask layout designs have overall aperture ratios, and each of the photomask layout designs comprises a first device region and a first dummy region; and
adjusting an aperture ratio of the first dummy region of at least one of the photomask layout designs to reduce an overall aperture ratio difference between the photomask layout designs.

2. The photomask design method according to claim 1, wherein after adjusting the aperture ratio of the first dummy region of at least one of the photomask layout designs, the overall aperture ratio difference between any two of the photomask layout designs ranges from 0% to 20%.

3. The photomask design method according to claim 1, wherein after adjusting the aperture ratio of the first dummy region of at least one of the photomask layout designs, the overall aperture ratio difference between any two of the photomask layout designs ranges from 0% to 15%.

4. The photomask design method according to claim 1, wherein after adjusting the aperture ratio of the first dummy region of at least one of the photomask layout designs, the overall aperture ratio difference between any two of the photomask layout designs ranges from 0% to 10%.

5. The photomask design method according to claim 1, wherein after adjusting the aperture ratio of the first dummy region of at least one of the photomask layout designs, the overall aperture ratio difference between any two of the photomask layout designs ranges from 0% to 5%.

6. The photomask design method according to claim 1, wherein a method of adjusting the aperture ratio of the first dummy region of at least one of the photomask layout designs comprises increasing the aperture ratio of the first dummy region of at least one of the photomask layout designs.

7. The photomask design method according to claim 1, wherein a method of adjusting the aperture ratio of the first dummy region of at least one of the photomask layout designs comprises reducing the aperture ratio of the first dummy region of at least one of the photomask layout designs.

8. A semiconductor manufacturing process, comprising:
providing photomasks formed by the photomask design method according to claim 1;
providing a substrate, wherein the substrate comprises a second device region and a second dummy region, the second device region corresponds to the first device region, the second dummy region corresponds to the first dummy region, the substrate has a fin portion and a dummy fin portion, the fin portion is located in the second device region, and the dummy fin portion is located in the second dummy region; and
performing ion implantation processes on the substrate by using patterned photoresist layers as masks, wherein
the patterned photoresist layers are formed by performing lithography processes by using the photomasks, and
after performing the ion implantation processes, a top-view pattern of a top surface of the dummy fin portion has various widths.

9. The semiconductor manufacturing process according to claim 8, wherein at least two of the ion implantation processes dope different area ranges of the dummy fin portion, and the different area ranges have an overlapping area.

10. The semiconductor manufacturing process according to claim 8, wherein at least two of the ion implantation processes dope different area ranges of the dummy fin portion, and the different area ranges are separated from each other.

11. The semiconductor manufacturing process according to claim 8, wherein a contour of the top-view pattern of the top surface of the dummy fin portion comprises an irregular shape.

12. The semiconductor manufacturing process according to claim 8, wherein a contour of the top-view pattern of the top surface of the dummy fin portion comprises a curved line.

13. The semiconductor manufacturing process according to claim 8, wherein a contour of the top-view pattern of the top surface of the dummy fin portion comprises a wavy shape.

14. The semiconductor manufacturing process according to claim 8, wherein a contour of the top-view pattern of the top surface of the dummy fin portion comprises a tip.

15. A semiconductor structure, comprising:
a substrate, wherein
the substrate comprises a device region and a dummy region,
the substrate has a fin portion and a dummy fin portion,
the fin portion is located in the device region,
the dummy fin portion is located in the dummy region, and
a top-view pattern of a top surface of the dummy fin portion has various widths.

16. The semiconductor structure according to claim 15, wherein a contour of the top-view pattern of the top surface of the dummy fin portion comprises an irregular shape.

17. The semiconductor structure according to claim 15, wherein a contour of the top-view pattern of the top surface of the dummy fin portion comprises a curved line.

18. The semiconductor structure according to claim 15, wherein a contour of the top-view pattern of the top surface of the dummy fin portion comprises a wavy shape.

19. The semiconductor structure according to claim 15, wherein a contour of the top-view pattern of the top surface of the dummy fin portion comprises a tip.

20. The semiconductor structure according to claim 15, wherein a top-view pattern of a top surface of the fin portion has a uniform width.
